(19) United States
(12) Patent Application Publication
(10) Pub. No.: US 2024/0039513 A1
(43) Pub. Date: Feb. 1, 2024

(54) STACKED RESONATOR WITH VARIABLE DENSITY ELECTRODE

(71) Applicant: Avago Technologies International Sales Pte. Limited, Singapore (SG)

(72) Inventor: Paul Bradley, Los Altos, CA (US)

(21) Appl. No.: 17/875,156

(22) Filed: Jul. 27, 2022

(51) Int. Cl. H03H 9/205; H03H 3/02; H03H 9/13

(52) U.S. Cl. CPC H03H 9/205; H03H 3/02; H03H 9/132

(57) ABSTRACT

A resonator may include two or more electrodes and one or more piezoelectric materials, where the two or more electrodes and the one or more piezoelectric materials are distributed in a direction. Further, at least one of the two or more electrodes may have a constant thickness along the direction and may include two or more regions having different densities, where the two or more regions are distributed in a plane normal to the direction and the two or more regions have the constant thickness along the direction.

### TECHNICAL FIELD

The present disclosure relates generally to an acoustic resonator and, more particularly, to a stacked resonator with a variable density electrode.

### BACKGROUND

Resonators (e.g., acoustic resonators) are used in many applications including, but not limited to, radio-frequency (RF) communication applications. For example, resonators are commonly used within RF passband filters on transmission and/or reception pathways. One class of resonators includes bulk acoustic-wave resonators formed from piezoelectric materials, which provide acoustic oscillations in response to time-varying electronic signals. For example, a piezoelectric material may expand or contract in response to an applied voltage. Further, such resonators may exhibit acoustic resonant modes (e.g., resonant frequencies, resonances, or the like) that may be exploited to provide desired properties when implemented within an electronic circuit such as, but not limited to, a filter.

It is becoming increasingly desirable to provide greater control over the particular resonant modes excitable in a resonator and/or a Q-factor of the resonator. However, current techniques are not well-suited for processes that benefit from planarization such as, but not limited to, stacked resonator designs. There is therefore a need to develop systems and methods to cure the above deficiencies.

### SUMMARY

A resonator is disclosed in accordance with one or more illustrative embodiments of the present disclosure. In one illustrative embodiment, the resonator includes two or more electrodes. In another illustrative embodiment, the resonator includes one or more piezoelectric materials, where the two or more electrodes and the one or more piezoelectric materials are distributed in a direction. In another illustrative embodiment, at least one of the two or more electrodes has a constant thickness along the direction and includes two or more regions having different densities. In another illustrative embodiment, the two or more regions are distributed in a plane normal to the direction and the two or more regions have the constant thickness along the direction.

A circuit is disclosed in accordance with one or more illustrative embodiments of the present disclosure. In one illustrative embodiment, the circuit includes one or more resonators. In another illustrative embodiment, at least one of the one or more resonators includes two or more electrodes and one or more piezoelectric materials, where the two or more electrodes and the one or more piezoelectric materials are distributed in a direction. In another illustrative embodiment, at least one of the two or more electrodes has a constant thickness along the direction and includes two or more regions having different densities. In another illustrative embodiment, the two or more regions are distributed in a plane normal to the direction and two or more regions have the constant thickness along the direction.

A method is disclosed in accordance with one or more illustrative embodiments of the present disclosure. In one illustrative embodiment, the method includes fabricating one or more piezoelectric materials. In another illustrative embodiment, the method includes fabricating two or more electrodes, where the two or more electrodes and the one or more piezoelectric materials are distributed in a direction. In another illustrative embodiment, the method includes fabricating at least one of the two or more electrodes to have a constant thickness along the direction and two or more regions having different densities, where the two or more regions are distributed in a plane normal to the direction.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, explain the principles of the invention.

### BRIEF DESCRIPTION OF DRAWINGS

The numerous advantages of the disclosure may be better understood by those skilled in the art by reference to the accompanying figures.

FIG. 1A is a cross-section view of a resonator, in accordance with one or more embodiments of the present disclosure.

FIG. 1B is a top view of the second electrode of FIG. 1A, in accordance with one or more embodiments of the present disclosure.

FIG. 1C is a cross-section view of a resonator with an electrode having three regions of different density, in accordance with one or more embodiments of the present disclosure.

FIG. 1D is a top view of the second electrode of FIG. 1C, in accordance with one or more embodiments of the present disclosure.

FIG. 2 is a cross-section view of a resonator configured as a double bulk acoustic wave resonator (DBAR) structure with an electrode having a constant thickness (T) and two regions of different densities, in accordance with one or more embodiments of the present disclosure.

FIG. 3 is a cross section view of a resonator configured as a DBAR structure with an electrode having a constant thickness (T) and three regions of different densities, where the three regions are formed as layers of two different materials, in accordance with one or more embodiments of the present disclosure.

FIG. 4 is a simplified schematic diagram of a filter including resonators, in accordance with one or more embodiments of the present disclosure.

FIG. 5 is a flow diagram illustrating steps performed in a method for fabricating a resonator, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

As used herein, directional terms such as “top,” “bottom,” “over,” “under,” “upper,” “upward,” “lower,” “down,” and “downward” are intended to provide relative positions for purposes of description and are not intended to designate an absolute frame of reference. Various modifications to the described embodiments will be apparent to those with skill in the art, and the general principles defined herein may be applied to other embodiments.

It is to be understood that depicted architectures are merely exemplary and that many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Additionally, unless otherwise indicated, a description indicating that one component is “connected to” another component or “between” two components indicates that such components are functionally connected and does not necessarily indicate that such components are physically in contact. Rather, such components may be in physical contact or may alternatively include intervening elements. Similarly, descriptions that a particular component is “fabricated over” another component (alternatively “located on,” “disposed on,” or the like) indicates a relative position of such components but does not necessarily indicate that such components are physically in contact. Such components may be in physical contact or may alternatively include intervening elements.

Embodiments of the present disclosure are directed to systems and methods providing a stacked resonator including an alternating sequence of electrodes and piezoelectric materials, where at least one electrode has a constant thickness (e.g., uniform thickness) and further includes two or more regions with different densities that are distributed in a plane of the interior electrode. An electrode may include any type of conductive material through which electricity may enter, leave, and/or flow (e.g., a metal, or the like). For example, the electrodes and the piezoelectric material may be distributed along a first direction (e.g., normal to a substrate). In this way, at least one of the electrodes may have a constant thickness in this first direction and may have two or more regions with different densities distributed in the plane normal to the first direction. A constant thickness may be relatively constant and need not be perfectly constant; the thickness may vary over the direction.

A resonator may include a device that exhibits mechanical oscillations in response to applied signals, or vice versa. In this way, resonators may provide mechanical responses to applied electrical signals or provide electrical signals in response to mechanical stress. Resonators are commonly used in filters for communications devices such as, but not limited to radio frequency (RF) communications devices.

For example, one type of resonator includes a piezoelectric material between two electrodes. A piezoelectric material may include any material or combination of materials that exhibits piezoelectric properties providing a modified structural state (e.g., a compressed structural state, an expanded mechanical state, mechanical stress, or the like) in response to an applied electric field, or vice versa. In this configuration, applying a signal (e.g., an RF signal, or a signal at any selected operational frequency) to one of the electrodes (or across the electrodes) may induce mechanical deformations in the piezoelectric material that result in the formation of acoustic waves in the device as a whole. Various types of resonators including piezoelectric materials in different configurations have been developed and include, but are not limited to, bulk acoustic wave (BAW) resonators, film bulk acoustic wave resonators (FBARs), or solidly mounted resonators (SMRs).

A resonator may exhibit one or more resonant frequencies based at least in part on various properties of the constituent materials (e.g., the electrodes, the piezoelectric material, any intervening materials, a substrate, or any additional materials) such as, but not limited to, physical layout, size, thickness, mechanical properties, and/or piezoelectric properties. A frequency response of such a device (e.g., a transmitted amplitude of an input signal through the device as a function of frequency) may thus vary based on the resonant frequencies and the properties of the constituent materials more generally. Further, one or more resonators can be configured to operate as a filter in which a frequency response of the filter may be based on the resonant frequencies of the one or more constituent resonators. For example, one or more resonators may be configured as, but not limited to, a low-pass filter, a high-pass filter, a bandpass filter, or a bandstop filter (e.g., a notch filter).

Additionally, some resonator designs include structures that impact and/or control various acoustic modes and thus the frequency response of the resonator. Various non-limiting examples of controlling acoustic modes are generally described in U.S. Pat. No. 7,280,007 issued on Oct. 9, 2007, U.S. Pat. No. 8,248,185 issued Aug. 21, 2012, U.S. Pat. No. 8,981,876 issued on Mar. 17, 2015, U.S. Pat. No. 9,219,464 issued on Dec. 22, 2015, and U.S. Pat. No. 10,727,808 issued on Jul. 28, 2020, which are all incorporated herein by reference in their entireties. For example, a resonator (e.g., formed form a piezoelectric material between two electrodes) may resonate with various modes. These modes, may include, but are not limited to: (1) a “piston” mode associated with compression or expansion along a direction normal to planes of the electrodes and piezoelectric material, and (2) various lateral modes along the planes of the electrodes and piezoelectric material. In many applications, the “piston” mode is a primary mode that contributes substantially to a desired or designed frequency response of the resonator, whereas lateral modes are generally spurious modes.

For example, some resonator designs include an area of increased mass around a perimeter of a resonator (commonly referred to as an outie) to provide a region of lower resonant frequency than an interior region to induce a well-defined acoustic impedance mismatch that improves the quality (Q) factor of the resonator. Such a structure may improve the Q-factor of the resonator by trapping lateral modes in the resonator and thus mitigate losses associated with these lateral modes. As an illustration, lateral modes may generally be reflected from edges of a resonator structure, but may be a source of loss due to defects or nonuniformities of these edges. To mitigate such losses, an outie may include a region with a well-defined thickness around the perimeter of the resonator of approximately a quarter wavelength of a lateral mode (or an integer multiple thereof) which may reflect with high efficiency, resulting in lower loss and a higher Q-factor for the resonator.

As another example, some resonator designs include an area of decreased mass (or density) around a perimeter of a resonator (commonly referred to as an innie) to provide a region of higher resonant frequency than an interior region in order to suppress lateral modes and thus isolate a desired resonant mode (e.g., a “piston” mode). Further, some designs incorporate both an innie and an outie to promote both isolation of a desired resonant mode and efficient trapping of remaining lateral modes. In such designs, a resonator may include an inner or central region, an innie surrounding the inner region having decreased mass (or density, e.g., d=m/v) relative to the inner region, and an outie surrounding the innie having increased mass (or density) relative to the inner region. In this way, the outie may trap lateral modes not fully suppressed by the innie.

It is contemplated herein that structures such as, but not limited to, innies and outies are typically formed as patterned structures integrated with or fabricated on top of one or both electrodes. For example, an outie may commonly be formed as a raised feature on an electrode whereas an innie may commonly be formed as a recessed feature on an electrode. In this way, a raised feature has the effect of raising the mass of the resonator relative to the inner region and a recessed feature has the effect of reducing the mass of the resonator relative to the inner region.

It is further contemplated herein that the formation of such raised and/or recessed structures on an electrode is not well-suited to stacked resonator designs including, but not limited to, double bulk acoustic wave resonators (double BAR or DBAR), stacked BAR (SBAR), or reversed stacked BAR (RSBAR) designs. Stacked resonator designs are described generally in U.S. Pat. No. 7,889,024 issued on Feb. 15, 2011, U.S. Pat. No. 9,847,768 issued Dec. 19, 2017, and U.S. Patent Publication No. 2009/0079514 published on Mar. 26, 2019, all of which are incorporated herein by reference in their entireties. Such stacked resonator designs typically include alternating layers of electrodes and piezoelectric materials, which may be beneficial for reducing various harmonic resonant modes (e.g., modes oscillating at harmonics of a desired “piston” mode).

As a non-limiting example, a resonator may include a first piezoelectric material between first and second electrodes and a second piezoelectric material between the second electrode and a third electrode in a stacked structure. Such a structure may be configured to provide that the first and second piezoelectric materials exhibit opposing mechanical responses (e.g., compression or expansion) to an input electrical signal, which may beneficially suppress harmonic modes such as, but not limited to, a second-order harmonic mode.

It is typically desirable to planarize various constituent layers of a stacked resonator (e.g., the electrodes and/or the piezoelectric materials) during processing to promote operation of the resonator within desired tolerances or specifications. For example, planarization may facilitate the fabrication of homogenous layers of material with constant thickness, which may beneficially mitigate spurious acoustic modes as well as promote desired electromechanical and thermal properties of the resonator.

However, it is further contemplated herein that planarization processes such as, but not limited to, chemical-mechanical-planarization (CMP) may degrade structures on an interior electrode designed to control acoustic modes such as, but not limited to, raised structures (e.g., an outie) or recessed structures (e.g., an innie). As a result, it may be difficult or impractical to provide such structures for acoustic mode control on internal electrodes of stacked resonators using typical techniques.

Embodiments of the present disclosure are directed to systems and methods for providing an electrode having a constant thickness and two or more regions with different densities that are distributed in a plane of the electrode. In some embodiments, an electrode having a constant thickness includes a first region (e.g., an inner region) with a first density, a second region surrounding the first region that has a second density lower than the first density, and a third region surrounding the second region that has a third density higher than the first density. In this way, the second region may operate as an innie (e.g., to suppress lateral modes) and the third region may operate as an outie (e.g., to trap lateral modes and promote a high Q-factor). Further, the constant thickness of the electrode across all density regions may enable the use of planarization techniques (e.g., CMP, or the like) on the electrode during fabrication. In this way, such an electrode may be implemented as an internal electrode in a stacked resonator structure in which constituent materials having constant (but not necessarily equal) thicknesses.

An electrode having a constant thickness and multiple regions of different density as disclosed herein may be formed in various ways within the spirit and scope of the present disclosure. As used herein, descriptions of a density of a particular region of an electrode refers to an average density of the electrode within the particular region. Put another way, different regions of different densities may also correspond to different masses within the regions, which impacts the associated resonant modes of the regions. In some embodiments, a particular region may be formed with multiple materials having different densities. Accordingly, the density of the region may be the average density of the different materials in the particular region based on the relative fractions of the materials in the particular region. For example, an electrode may be formed as two or more materials arranged in two or more layers, where different regions may have different numbers or thicknesses of layers of any of the two or more materials. In this configuration, a ratio of thicknesses of the materials in the different regions may vary between different regions to provide the different densities in the regions.

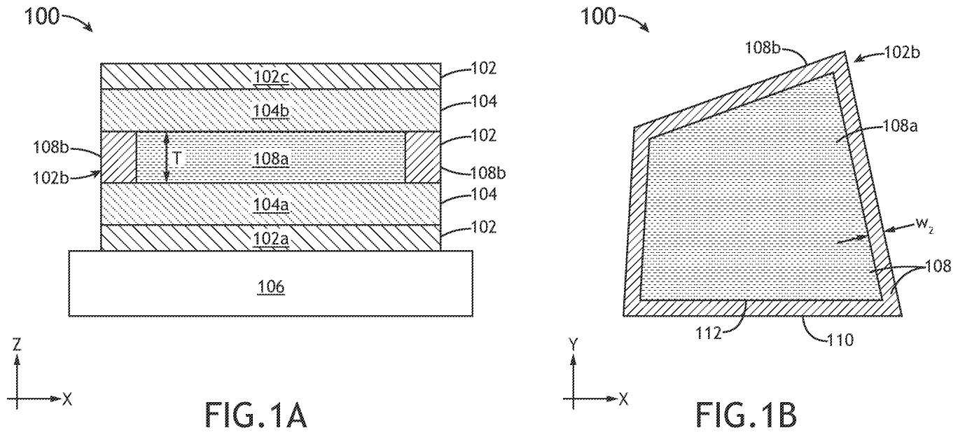

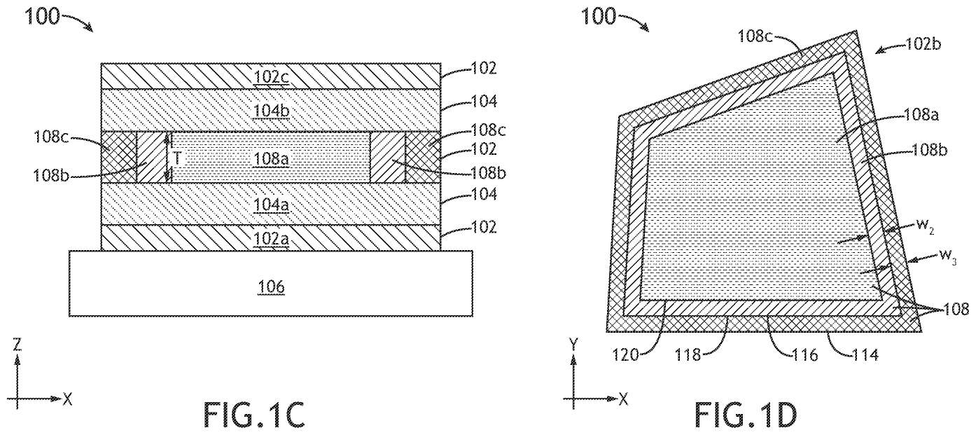

Referring now to FIGS. 1-5, systems and methods providing a resonator having multiple layers of piezoelectric materials and electrodes in a stacked structure, where an interior electrode has a constant thickness and two or more regions of different density.

FIG. 1A is a cross-section view of a resonator 100, in accordance with one or more embodiments of the present disclosure.

In some embodiments, the resonator 100 includes electrodes and piezoelectric materials arranged in a stack along a first direction (e.g., a stack direction). The resonator 100 may thus be referred to as a stacked resonator 100. In particular, the resonator 100 may include at least three electrodes 102 and at least two piezoelectric materials 104 in an alternating sequence.

As an illustration, the resonator 100 depicted in FIG. 1A includes a stack with a first electrode 102a, a first piezoelectric material 104a, a second electrode 102b, a second piezoelectric material 104b, and a third electrode 102c arranged along a first direction (here, the Z direction). Although not shown, the resonator 100 may additionally include intervening layers between any of the electrodes 102 or piezoelectric materials 104. For example, the resonator 100 may include one or more seed layers used to promote and/or control the growth of any of the constituent materials.

In some embodiments, the resonator 100 is mounted on a substrate 106. The substrate 106 may include any material such as, but not limited to, a semiconductor wafer. In some embodiments, though not shown, the resonator 100 is mounted at least partially over a cavity in the substrate 106.

A resonator 100 including an alternating sequence of electrodes 102 and piezoelectric materials 104 with at least three electrodes 102 and at least two piezoelectric materials 104 will have at least one electrode 102 located between two piezoelectric materials 104, which is referred to herein as an interior electrode 102. In FIG. 1A, the second electrode 102b is an interior electrode 102 since it is located between the first piezoelectric material 104a and the second piezoelectric material 104b.

It is noted that the resonator 100 depicted in FIG. 1A may be, but is not required to be, considered as two stacked FBARs sharing a common electrode (e.g., an interior electrode). For example, the first electrode 102a, the first piezoelectric material 104a, and the second electrode 102b may be a first FBAR, while the second electrode 102b, the second piezoelectric material 104b, and the third electrode 102c may be a second FBAR. Such an arrangement may provide enhanced control over the frequency response of the resonator 100 based on the mechanical coupling between the stacked FBAR structures and the directions of motion associated with the constituent piezoelectric materials 104.

A piezoelectric material 104 in a resonator 100 may expand or contract along a compression axis (C-axis) in response to an applied electric field (e.g., an applied voltage between two electrodes 102 surrounding the piezoelectric material 104), where the C-axis is typically based on an orientation of a crystalline structure of the piezoelectric material 104. This expansion or contraction may be referred to as a “piston” resonant mode as described previously herein.

Some combinations of material polarization and electric field may result in a piezoelectric material 104 that is compression positive (e.g., a Class I piezoelectric material), which compresses along a C-axis in response to a particular electric field. As another example, some combinations of material polarization and electric field may result in a piezoelectric material 104 that is compression negative (e.g., a Class II piezoelectric material), which expands along a C-axis in response to the same electric field.

As used herein, the term C-axis vector is used to describe both whether a piezoelectric material 104 is compression positive or compression negative as well as an axis of compression or expansion (e.g., a C-axis). In particular, the C-axis vector is depicted as an arrow where an orientation of a C-axis vector is indicative of the C-axis, and a direction of the arrow indicates whether the piezoelectric material is compression positive or compression negative along this C-axis.

It is recognized that arranging a resonator 100 as depicted in FIG. 1 to provide that the first piezoelectric material 104a and the second piezoelectric material 104b provide opposite piezoelectric responses (e.g., expansion or contraction) to an applied signal may at least partially suppress undesired resonant modes such as, but not limited to, second harmonic resonant modes. In particular, such an arrangement provides that the first piezoelectric material 104a contracts while the second piezoelectric material 104b expands (or vice versa) such that that second harmonic resonant modes of the resonator 100 as a whole are suppressed.

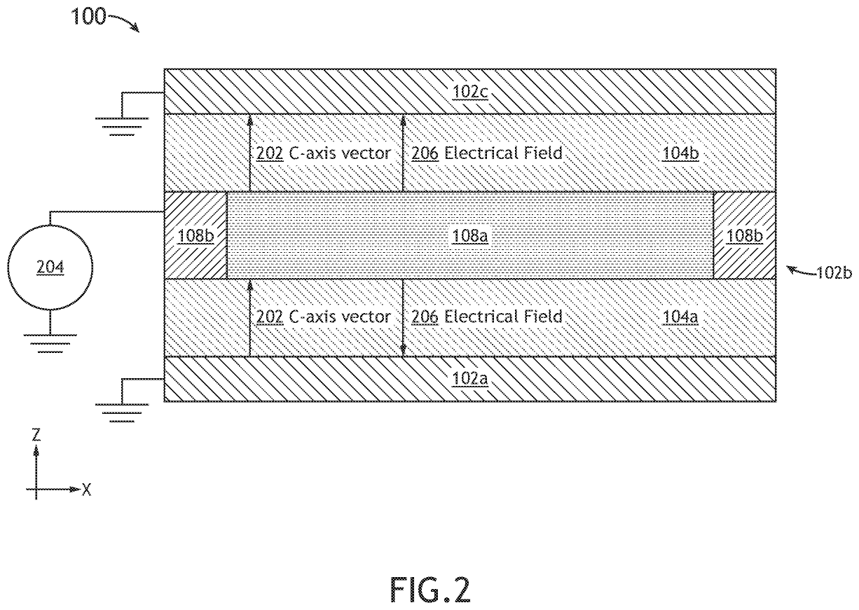

FIG. 2 is a cross-section view of a resonator 100 configured as a DBAR structure with an electrode 102 (e.g., the second electrode 102b) having a constant thickness (T) and two regions 108 of different densities, in accordance with one or more embodiments of the present disclosure. DBAR structures are generally described in U.S. Pat. No. 7,889,024 issued on Feb. 15, 2011, which is incorporated herein by reference in its entirety.

In this resonator 100, the first piezoelectric material 104a and the second piezoelectric material 104b have a C-axis vector 202 along a common direction. Further, an input signal (e.g., provided by source 204) is provided to the second electrode 102b (e.g., an interior electrode), while the first electrode 102a and the third electrode 102c are connected to a common voltage (e.g., ground as illustrated in FIG. 2 or, alternatively, any selected voltage). In this way, the first piezoelectric material 104a and the second piezoelectric material 104b have opposite configurations for the relative directions of the applied electric field and the C-axis vector for any input signal. As an illustration, FIG. 2 depicts a configuration in which an applied electric field 206 opposes the C-axis vector 202 of the first piezoelectric material 104a, whereas the applied electric field 206 is aligned with the C-axis vector 202 of the second piezoelectric material 104b.

It is to be understood, however, that FIG. 2 and the associated description is provided solely for illustrative purposes and should not be interpreted as limiting. Rather, various designs of a resonator 100 including a stacked sequence of piezoelectric materials 104 and electrodes 102 are possible. In some embodiments, the C-axis vector 202 of the first piezoelectric material 104a is antiparallel to the C-axis vector 202 of the second piezoelectric material 104b. Such a structure may be referred to as an RSBAR and is generally described in U.S. Pat. No. 9,847,768 issued on Dec. 19, 2017, which is incorporated herein by reference in its entirety.

It is contemplated herein that it may be desirable to planarize one or more layers of the resonator 100 (e.g., any of the electrodes 102, any of the piezoelectric materials 104, or the like) during fabrication to promote uniform and controlled growth of the various layers and thus to promote control of the frequency response of the resonator 100. For instance, variations in the constituent layers may result in spurious resonant modes during operation, which may negatively impact performance.

In some embodiments, the resonator 100 includes at least one electrode 102 having a constant thickness and two or more regions of different density. In this way, the electrode may include features configured to control resonant modes and/or a Q-factor of the resonator 100 (e.g., an innie and/or an outie) while also remaining compatible with planarization processes. It is contemplated herein that any electrode 102 (or multiple electrodes 102) may have a constant thickness and two or more regions of different density as disclosed herein. In this way, the depictions of the second electrode 102b as having two or more regions of different density are merely illustrative and should not be interpreted as limiting on the present disclosure. For example, any combination of the electrodes 102a-c may have uniform thickness and multiple regions of different density. Further, in some embodiments, though not shown, a resonator 100 includes two electrodes 102 surrounding a piezoelectric material 104 (e.g., an FBAR structure), where one or both of the electrodes 102 has a uniform thickness and multiple regions of different density.

Referring now to FIGS. 1A-1D, the formation of an electrode 102 with a constant thickness (T) and two or more regions 108 of different density (e.g., the second electrode 102b, or the like) is described in greater detail, in accordance with one or more embodiments of the present disclosure. In particular, FIGS. 1A-1D depict the second electrode 102b as having the constant thickness (T) and the two or more regions 108 of different density. However, it is to be understood that this is merely illustrative and any or all of the electrodes 102a-c may have a constant thickness and two or more regions 108 having different densities. Further, the thickness as well as the number or configuration of regions 108 of different density may vary between the electrodes 102a-c.

In some embodiments, the second electrode 102b includes multiple regions 108 of different density (e.g., average density) distributed across a plane of the electrode 102, where the plane of the electrode 102 corresponds to a plane normal to a stack direction (e.g., a first direction) in which the components of the resonator 100 are distributed (e.g., the Z direction in FIGS. 1A-1D). The regions 108 may be arranged in any distribution within the plane of the electrode 102. Further, the electrode 102 may have a constant thickness (T) in the stack direction such that all electrode 102 have this same constant thickness (T).

In some embodiments, the second electrode 102b includes at least an inner region 108 (e.g., including a center of the electrode 102) and at least one frame region 108 that surrounds the inner region and has a constant width in the plane of the electrode 102. Such a frame region 108 may extend to a perimeter of the piezoelectric materials 104 and thus have the same shape as the piezoelectric materials 104, but is not required to. For example, the piezoelectric materials 104 (e.g., the first piezoelectric material 104a and the second piezoelectric material 104b) may have a common shape that may define an active area of the resonator 100. The piezoelectric materials 104 may generally have any suitable shape. In some embodiments, the piezoelectric materials 104 are shaped as a polygon. Further, in some embodiments, the polygonal shape of the piezoelectric materials 104 has no parallel sides to mitigate the formation of standing lateral resonant modes.

A frame region 108 may have a higher density than the inner region 108 to operate as an outie or may have a lower density than the inner region 108 to operate as an innie. As an illustration, the second electrode 102b of the resonator 100 in FIGS. 1A-1B includes two regions 108 of different density. FIG. 1B is a top view of the second electrode 102b of FIG. 1A, in accordance with one or more embodiments of the present disclosure. In particular, FIGS. 1A-1B depict a first region 108a (e.g., an inner region, a central region, or the like) and a second region 108b surrounding the first region 108a, where the first region 108a and the second region 108b are distributed in a plane of the second electrode 102b (here the X-Y plane in FIG. 1B).

Further, the second region 108b has a constant width (w₂) in the plane of the electrode. The second region 108b may thus be a frame region 108 and may have a higher or lower density relative to the first region 108a to be an outie or an innie, respectively. In some embodiments, as illustrated in FIG. 1B, the second region 108b is arranged around a perimeter of the resonator 100 (e.g., as defined by the shapes of the first piezoelectric material 104a and the second piezoelectric material 104b). In this way, both an outer perimeter 110 and an inner perimeter 112 of the second region 108b have a common shape with the piezoelectric materials 104 (not shown in FIG. 1B for clarity).

As another illustration, FIG. 1C is a cross-section view of a resonator 100 with an electrode 102 (e.g., the second electrode 102b) having three regions 108a-c of different density, in accordance with one or more embodiments of the present disclosure. FIG. 1D is a top view of the second electrode 102b of FIG. 1C, in accordance with one or more embodiments of the present disclosure. As depicted in FIGS. 1C-1D, the three regions 108a-c of the second electrode 102b are distributed along the plane of the second electrode 102b (e.g., the X-Y plane of FIG. 1D).

In particular, FIGS. 1C-1D depict a first region 108a (e.g., an inner region, a central region, or the like), a second region 108b surrounding the first region 108b, and a third region 108c surrounding the second region 108b. Further, the second region 108b and the third region 108c are both depicted as frame regions 108 with widths w₂ and w₃, respectively. Additionally, FIGS. 1C-1D depict the second region 108b and the third region 108c as having a common shape as the piezoelectric materials 104. In particular, the outer perimeter 114 of the third region 108c and the inner perimeter 116 of the third region 108c have a common shape as the piezoelectric materials 104 to provide a frame with a width (w₃). Similarly, the outer perimeter 118 of the second region 108b and the inner perimeter 120 of the second region 108b have a common shape as the piezoelectric materials 104 to provide a frame with a width (w₂).

The regions 108a-c may have any selected dimensions and densities. In some embodiments, the first region 108a has a first density, the second region 108b has a second density that is lower than the first density, and the third region 108c has a third density that is higher than the first density. In this way, the second region 108b may be an innie and the third region 108c may be an outie.

It is to be understood, however, that the number and arrangements of regions 108 of different densities depicted in FIGS. 1A-1D are merely illustrative and should not be interpreted as limiting. Rather, an electrode 102 of a resonator 100 having a constant thickness may include any number or arrangement of regions 108 of different density. Further, any of the electrodes 102 of a resonator 100 may have regions 108 of different density. For example, any combination of the electrodes 102a-c depicted in FIGS. 1A-1D may have a constant thickness and regions 108 of different density. In cases where a resonator 100 includes multiple electrodes 102 with regions 108 of varying density, these electrodes 102 may have different thicknesses, numbers of regions 108 of varying density, arrangement of the regions 108 of varying density, or the like.

An electrode 102 with multiple regions 108 of different density may be formed by any number or arrangement of materials. An electrode 102 may include any electrically-conductive material (e.g., a material with an electrical resistance below a selected threshold) such as, but not limited to, tungsten (W), molybdenum (Mo), or ruthenium (Ru).

In some embodiments, an electrode 102 is formed from two or more materials having different densities, where each region 108 includes at least one of the two or more materials, and where a density in each region 108 is controlled based on relative fractions of the two or more materials. In this way, the density in each region 108 may correspond to an average density of the materials in the region 108. As a non-limiting illustration, tungsten has a density of approximately 19.3 grams per cubic centimeter (g/cm³), whereas molybdenum has a density of approximately 10.2 g/cm³. Accordingly, the density in any particular region of the electrode 102 (e.g., the average density) may be varied by changing the ratio of tungsten and molybdenum between 10.2 g/cm³ (pure molybdenum) and 19.3 g/cm³ (pure tungsten). It is to be understood, however, that this is merely an illustration and that the electrode 102 may generally be formed from any ratio of any number of materials.

Materials of different density within a region 108 of the electrode 102 may be arranged in any distribution.

In some embodiments, at least one region 108 includes a single material. In some embodiments, at least one region 108 includes two or more materials distributed among two or more layers. For example, a region 108 may be formed as a stack of two or more layers distributed in the stack direction (e.g., the first direction or the Z direction in FIGS. 1A-1D) up to the constant thickness of the electrode 102 as a whole. The density of such a region 108 may thus be controlled based on the fractional thicknesses of layers of each constituent material that contributes to the total thickness (T) of the electrode 102.

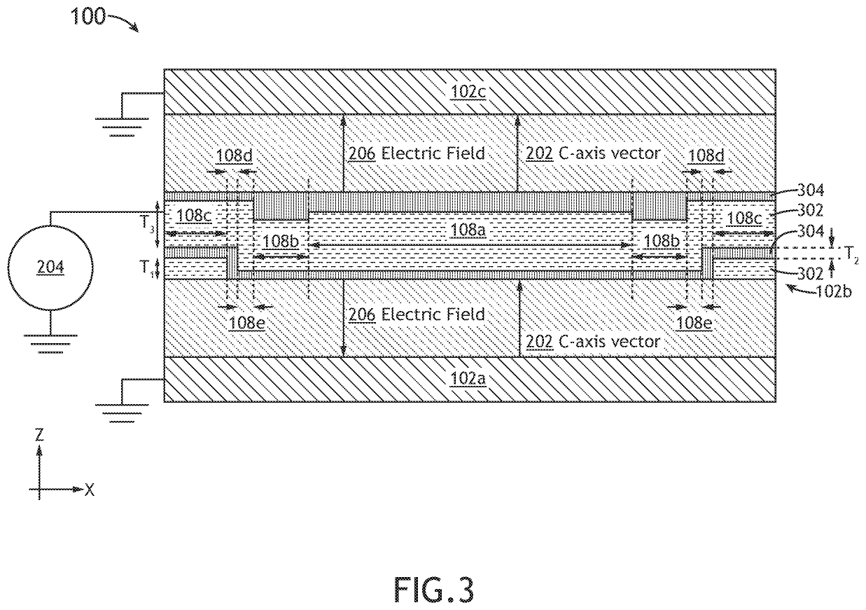

FIG. 3 is a cross section view of a resonator 100 configured as a DBAR structure with the second electrode 102b having a constant thickness (T) and three regions 108 of different densities, where the three regions 108a-c are formed as layers of two different materials, in accordance with one or more embodiments of the present disclosure. For example, the resonator 100 in FIG. 3 corresponds to a variation of the resonator 100 illustrated in FIGS. 1C and 1D in which the second electrode 102 has a constant thickness (T).

In particular, the second electrode 102b of the resonator 100 in FIG. 3 is formed as a multi-layer stacked structure including a first electrode material 302 having a relatively high density (e.g., tungsten) and a second electrode material 304 having a relatively low density (e.g., molybdenum), where the relative thicknesses of the first electrode material 302 and the second electrode material 304 differ between the regions 108a-c.

In FIG. 3, the first region 108a has a first density based on a first distribution of fractional thicknesses of the first electrode material 302 and the second electrode material 304. The second region 108b has a second density based on a second distribution of fractional thicknesses of the first electrode material 302 and the second electrode material 304. For example, the second region 108b includes a higher fractional thickness of the second electrode material 304 than the first region 108a such that the second density is lower than the first density. In this way, the second region 108 is an innie and may facilitate suppression of spurious modes in the resonator 100. The third region 108c has a third density based on a third distribution of fractional thicknesses of the first electrode material 302 and the second electrode material 304. For example, the third region 108c has a higher fractional thickness of the first electrode material 302 than the first region 108a such that the third density is higher than the first density. In this way, the third region 108c is an outie and may increase the Q-factor of the resonator 100.

It is contemplated herein that the impact of any particular region 108 of an electrode 102 (e.g., the second electrode 102b in FIG. 3) on a frequency response of the resonator 100 as a whole may depend substantially on the density of the region 108 along the stack direction (e.g., the direction of oscillation of the desired “piston” mode of the resonator 100) and the layout in the plane of the electrode 102 (e.g., a shape of the region 108). Accordingly, any particular region 108 may have any number of layers of any number of materials that provides a desired density through the stack direction.

As an illustration, the second electrode 102b of the resonator 100 in FIG. 3 is formed from alternating layers of the first electrode material 302 and the second electrode material 304 that have been patterned (e.g., using lithographic exposure of a photomask and subsequent etching or any other suitable fabrication process) to provide different thicknesses in the different regions 108. For example, the second electrode 102b may be formed by depositing a first layer of the first electrode material 302 and patterning this first electrode material 302 to form a frame in the shape of the third region 108c (e.g., the outie) with a first thickness (T₁), depositing a first layer of the second electrode material 304 (e.g., as a cladding layer) with a second thickness (T₂), depositing a second layer of the first electrode material 302 with a third thickness (T₃), depositing an third layer of the first electrode material 302 and patterning this third layer of the first electrode material 302 in a shape of the first region 108a (e.g., the inner region), and depositing a second layer of the second electrode material 304 (e.g., as a second cladding layer) with a thickness sufficient to fill all recesses. Subsequent to these steps, the second cladding layer of second electrode material 304 may be planarized using any technique such as, but not limited to, CMP to provide a constant thickness across the entire second electrode 102b. In this way, subsequent layers (e.g., the second piezoelectric material 104b) may be fabricated on the planarized surface and the various regions 108 of different density may remain.

It is noted that the above steps for fabricating the second electrode 102b (or any electrode 102 more generally) may result in one or more additional regions 108 of varying density. For example, the deposition of the first layer of the second electrode material 304 may create a region 108d with a width associated with a width of this layer of the second electrode material 304 along the plane of the electrode 102. As another example, the deposition of the second layer of the first electrode material 302 may create a region 108e with a width associated with a width of this layer of the first electrode material 302 along the plane of the electrode 102. In some cases, the widths of such regions 108 are sufficiently small that the impact of such regions 108 on the frequency response of the resonator 100 as a whole are negligible. In some cases, the design of the electrode 102 includes a known or simulated impact of these regions 108.

It is to be understood, however, that the particular design and/or series of fabrication steps associated with the particular resonator 100 depicted in FIG. 3 is merely illustrative and should not be interpreted as limiting the present disclosure. Rather, the second electrode 102b may have any number of regions 108 of different density having any shape, where the thickness (T) of the second electrode 102b is constant. Further, as described previously herein, any of electrodes 102a-c may have a constant thickness and multiple regions of varying density. In this way, the descriptions of the second electrode 102b are also merely illustrative.

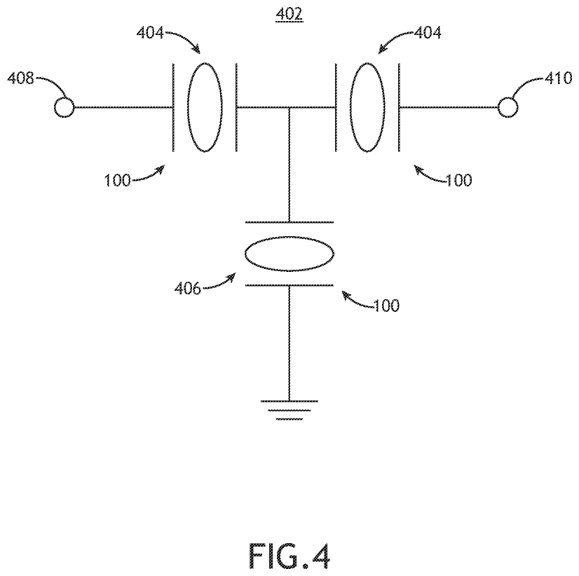

Referring now to FIG. 4, a circuit including at least one resonator 100 as disclosed herein is described in greater detail, in accordance with one or more embodiments of the present disclosure. A circuit (e.g., an electric circuit, an electrical circuit, or the like) may generally include any number of devices through which an electrical current may flow such as, wires (or other conductive paths), resistors, capacitors, inductors, diodes, or active components (e.g., amplifiers, or the like).

It is contemplated herein that a resonator 100 with at least one electrode 102 having a constant thickness and two or more regions 108 of different density may be used within any suitable type of circuit (e.g., electrical circuit) suitable for any application including, but not limited to, filters, RF communication systems, or sensors. In this way, a circuit may include at least one resonator 100 as disclosed herein and any number of additional components including, but not limited to, additional resonators fabricated using other techniques, passive components (e.g., resistors, capacitors, inductors, or the like), or active components (e.g., amplifiers, or the like).

FIG. 4 is a simplified schematic diagram of a filter 402 including resonators 100, in accordance with one or more embodiments of the present disclosure. In particular, FIG. 4 depicts a filter 402 including two series resonators 404 and a shunt resonator 406. For example, the series resonators 404 are in series between an input terminal 408 and an output terminal 410, while the shunt resonator 406 is connected between ground and a node between any of the series resonators 404. It is contemplated herein that the filter 402 may operate as a band-pass filter or a band-reject filter (e.g., a notch filter, a bandstop filter, or the like) depending on resonant frequencies of the series resonators 404 and the shunt resonator 406. In some embodiments, the filter 402 includes at least one resonator 100 having at least one electrode 102 with a constant thickness and multiple regions 108 of different density. For example, in FIG. 4, the series resonators 404 and the shunt resonator 406 are all formed as resonators 100 having at least one electrode 102 with a constant thickness and multiple regions 108 of different density.

It is to be understood that FIG. 4 and the associated description is provided solely for illustrative purposes and should not be interpreted as limiting. For example, the filter 402 may include any number of series resonators 404 or shunt resonators 406. More generally, at least one resonator 100 having at least one electrode 102 with a constant thickness and multiple regions 108 of different density as disclosed herein may be implemented within any filter design including, but not limited to, a ladder design or a lattice design. Additionally, a resonator 100 as disclosed herein may be implemented within any filter providing any type of frequency response such as, but not limited to, a low-pass filter, a high-pass filter, a band-pass filter, or a band-reject filter.

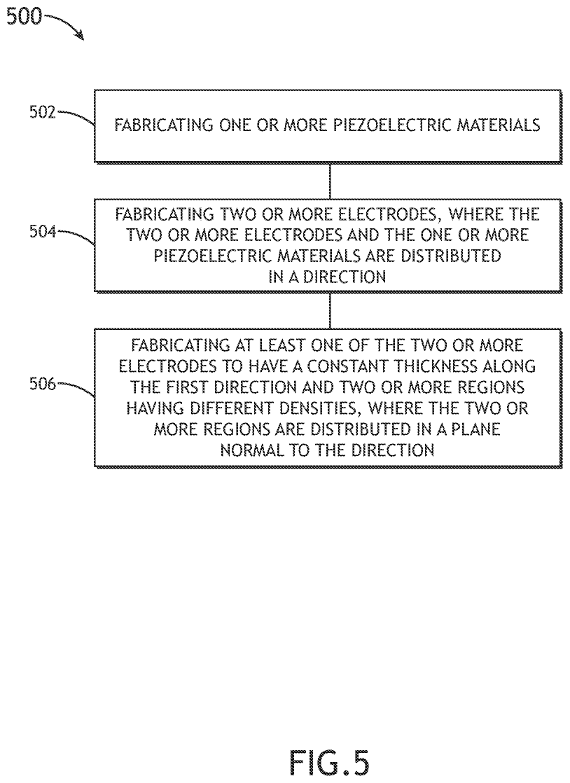

Referring now to FIG. 5, FIG. 5 is a flow diagram illustrating steps performed in a method 500 for fabricating a resonator 100, in accordance with one or more embodiments of the present disclosure. It is to be understood that the method 500 is not limited to the particular steps depicted in FIG. 5. In some embodiments, the method 500 may include additional steps, which may be performed before the depicted steps, after the depicted steps, and/or between any of the depicted steps. In some embodiments, not all of the steps depicted in FIG. 5 are performed.

In some embodiments, the method 500 includes a step 502 of fabricating one or more piezoelectric materials. In some embodiments, the method 500 includes a step 504 of fabricating two or more electrodes, where the two or more electrodes and the one or more piezoelectric materials are distributed in a direction (e.g., a stack direction). For example, the two or more electrodes and the one or piezoelectric materials may be fabricated in steps 502 and 504 as a resonator in which the each of the one or more piezoelectric materials are located between two of the two or more electrodes. In some embodiments, the resonator includes a single piezoelectric material between two electrodes (e.g., an FBAR). In some embodiments, the stack structure includes an alternating series of electrodes and piezoelectric materials (e.g., a DBAR, an RSBAR, or the like).

In some embodiments, the method 500 includes a step 506 of fabricating at least one of the two or more electrodes to have a constant thickness along the first direction and two or more regions having different densities, wherein the two or more regions are distributed in a plane normal to the direction (e.g., normal to the stack direction). In some embodiments, the two or more regions include a first region having a first density and a second region surrounding the first region having a second density. In the case that the second density is higher than the first density, the second region may be an outie that may increase the Q-factor of the resonator (e.g., relative to a resonator in which the electrodes have constant densities). In the case that the second density is lower than the first density, the second region may be an innie that may facilitate suppression of spurious resonant modes.

In some embodiments, the two or more regions further include a third region surrounding the second region with a third density. In the case that the second density is lower than the first density and the third density is higher than the first density, the second region may be an innie and the third region may be an outie to achieve both suppression of spurious modes and an increased Q-factor.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A resonator comprising:
two or more electrodes; and
one or more piezoelectric materials, wherein the two or more electrodes and the one or more piezoelectric materials are distributed in a direction;
wherein at least one of the two or more electrodes has a constant thickness along the direction and includes two or more regions having different densities, wherein the two or more regions are distributed in a plane normal to the direction, the two or more regions having the constant thickness along the direction.

2. The resonator of claim 1, wherein the two or more regions comprise:
a first region having a first density; and
a second region surrounding the first region having a second density different than the first density.

3. The resonator of claim 2, wherein a width of the second region in the plane normal to the direction is constant.

4. The resonator of claim 2, wherein the two or more regions further comprise:
a third region surrounding the second region having a third density different than the first and second densities.

5. The resonator of claim 4, wherein the second density is lower than the first density, wherein the third density is higher than the first density.

6. The resonator of claim 4, wherein a width of the third region in the plane normal to the direction is constant.

7. The resonator of claim 1, wherein the two or more electrodes comprise a first electrode, a second electrode, and a third electrode, wherein the one or more piezoelectric materials comprise a first piezoelectric material disposed between the first and second electrodes and a second piezoelectric material disposed between the second and third electrodes, wherein the second electrode is disposed between the first and second piezoelectric material.

8. The resonator of claim 7, wherein the second electrode has the constant thickness along the direction and includes the two or more regions having different densities.

9. The resonator of claim 1, wherein at least one of the two or more regions is formed as two or more materials disposed in two or more layers.

10. The resonator of claim 9, wherein the two or more materials comprise:
at least two of tungsten, molybdenum, or ruthenium.

11. A circuit comprising:
one or more resonators, wherein at least one of the one or more resonators comprises:
two or more electrodes; and
one or more piezoelectric materials, wherein the two or more electrodes and the one or more piezoelectric materials are distributed in a direction;
wherein at least one of the two or more electrodes has a constant thickness along the direction and includes two or more regions having different densities, wherein the two or more regions are distributed in a plane normal to the direction, the two or more regions having the constant thickness along the direction.

12. The circuit of claim 11, wherein the two or more regions comprise:
a first region having a first density; and
a second region surrounding the first region having a second density different than the first density.

13. The circuit of claim 12, wherein the two or more regions further comprise:
a third region surrounding the second region having a third density different than the first and second densities, wherein a width of the second region in the plane normal to the direction is constant, wherein a width of the third region in the plane normal to the direction is constant.

14. The circuit of claim 13, wherein the second density is lower than the first density, wherein the third density is higher than the first density.

15. The circuit of claim 11, wherein the two or more electrodes comprise a first electrode, a second electrode, and a third electrode, wherein the one or more piezoelectric materials comprise a first piezoelectric material disposed between the first and second electrodes and a second piezoelectric material disposed between the second and third electrodes, wherein the second electrode is disposed between the first and second piezoelectric material.

16. The circuit of claim 15, wherein the second electrode has the constant thickness along the direction and includes the two or more regions having different densities.

17. The circuit of claim 11, wherein at least one of the two or more regions is formed as two or more materials disposed in two or more layers.

18. The circuit of claim 17, wherein the two or more materials comprise:
at least two of tungsten, molybdenum, or ruthenium.

19. A method comprising:
fabricating one or more piezoelectric materials;
fabricating two or more electrodes, wherein the two or more electrodes and the one or more piezoelectric materials are distributed in a direction; and
fabricating at least one of the two or more electrodes to have a constant thickness along the direction and two or more regions having different densities, wherein the two or more regions are distributed in a plane normal to the direction.

20. The method of claim 19, wherein fabricating at least one of the two or more electrodes to have the constant thickness along the direction and two or more regions having different densities comprises:
fabricating at least one of the two or more regions as two or more materials disposed in two or more layers.
